(19) United States
(12) Patent Application Publication
(10) Pub. No.: US 2014/0218040 A1
(43) Pub. Date: Aug. 7, 2014

(54) METHOD FOR ESTIMATING THE STATE OF CHARGE OF A BATTERY, AND BATTERY MANAGEMENT SYSTEM USING THE METHOD

(71) Applicant: SAMSUNG SDI CO., LTD., Yongin-si (KR)

(72) Inventor: Jong-Hoon Kim, Yongin-si (KR)

(73) Assignee: Samsung SDI Co., Ltd., Yongin-si (KR)

(21) Appl. No.: 13/756,999

(22) Filed: Feb. 1, 2013

(30) Foreign Application Priority Data
Feb. 1, 2013 (KR) 10-2013-0011793

(51) Int. Cl. G01R 31/36

(52) U.S. Cl. CPC G01R 31/362
USPC 324/426

(57) ABSTRACT

A method of estimating a state of charge (SOC) of a battery and a battery management system (BMS) using the method. According to the method of estimating the SOC of the battery, terminal voltage data is collected by periodically measuring a terminal voltage of the battery. Voltage data of a low frequency component is extracted by performing discrete wavelet transform (DWT) based multi-resolution analysis on the terminal voltage data. The SOC of the battery is estimated based on the voltage data of the low frequency component.

### CROSS-REFERENCE TO RELATED APPLICATIONS

This application claims the benefit of Korean Patent Application No. 10-2013-0011793, filed on Feb. 1, 2013, in the Korean Intellectual Property Office, the disclosure of which is incorporated herein in its entirety by reference.

### BACKGROUND

1. Field

One or more embodiments of the present invention relate to a method of estimating a state of charge (SOC) of a battery and a battery management system (BMS) using the method, and more particularly, to a method of estimating an SOC of a battery by using a discrete wavelet transform (DWT) and a BMS using the method.

2. Description of the Related Art

The performance of batteries directly influences the performance of cars that use electric energy, and thus the performance of each battery cell needs to be excellent and a battery management system capable of measuring a battery temperature, a cell voltage, overall battery voltage and current, etc. and efficiently managing charging and discharging of batteries is also required.

A conventional BMS uses a method of estimating a state of charge (SOC) by current integration to determine the SOC of a battery. The conventional BMS has also used a method of previously determining a relationship between the SOC and factors such as an open circuit voltage (OCV) or a discharge voltage, an internal resistance, a temperature, a discharge current, etc., detecting at least two factors, and detecting the SOC corresponding to the detected factors.

In the SOC estimation method using the current integration, problems in that an initial value is not correct, measurement errors are accumulated, and an input current is not wholly converted to electric energy occurs, which deteriorates accuracy. Even if the relationship between the SOC and the OCV, etc. is determined, since batteries differ in terms of their characteristics, there are problems in that the relationship between the SOC and the OCV, etc. needs to be experimentally calculated through a complicated experiment for each battery, and a calculated value is also not accurate.

To overcome these disadvantages, as a method of concurrently using the above two methods, an adaptive method of estimating an SOC based on an extended Kalman filter (EKF) using an equivalent circuit model of a battery is proposed. Information related to the estimated SOC is obtained through a state equation, the obtained information is applied to a measurement equation, and an estimation voltage generated according to the relationship between the SOC and the OCV is compared to an actual voltage. In this regard, in a case where a charging and discharging current profile has an instant high current or a fast dynamic, since an error occurs in the equivalent circuit model, the above estimation of the SOC based on the equivalent circuit model is inaccurate.

In such an adaptive method, the above disadvantage may be solved and estimation performance may be increased by increasing an inner state of a system, but an algorithm becomes complicated and expenses increase. To solve these problems, although degradation of the SOC estimation performance is inhibited by reducing the inner state of the system to a minimum and adding a noise model to the algorithm, increases in algorithm complexity due to the addition of the noise model and expenses are still problematic. Accordingly, simplification of the algorithm while maintaining the estimation performance of the algorithm and a reduction in expenses are required.

### SUMMARY

One or more embodiments of the present invention include methods of concisely and accurately estimating a state of charge (SOC) of a battery by removing an existing noise model.

One or more embodiments of the present invention include battery management systems (BMSs) that use the methods of concisely and accurately estimating the SOC of the battery.

According to one or more embodiments of the present invention, a method of estimating a state of charge (SOC) of a battery, the method including: collecting terminal voltage data by periodically measuring a terminal voltage of the battery; extracting voltage data of a low frequency component by performing discrete wavelet transform (DWT) based multi-resolution analysis on the terminal voltage data; and estimating the SOC of the battery based on the voltage data of the low frequency component.

The terminal voltage data may be separated into voltage data of a plurality of frequency bands through the DWT-based multi-resolution analysis. The voltage data of the low frequency component may be voltage data of a lowest frequency band from among the voltage data of the plurality of frequency bands.

The terminal voltage data may be separated into first proximity voltage data and first detailed voltage data by performing low pass filtering and high pass filtering on the terminal voltage data. First proximity voltage sampling data may be generated by performing down-sampling on the first proximity voltage data to select odd numbered data or even numbered data of the first proximity voltage data. The first proximity voltage sampling data may be separated into second proximity voltage data and second detailed voltage data by performing low pass filtering and high pass filtering on the first proximity voltage sampling data. The terminal voltage data may be separated into nth proximity voltage data and first through nth detailed voltage data (where n is a natural number) by repeating operations of performing down-sampling and performing high pass filtering and low pass filtering. The voltage data of the low frequency component may be the nth proximity voltage data.

Coefficients of a low pass filter (LPF) for performing low pass filtering may be {0.0352, −0.0854, −0.1350, 0.4599, 0.8069, 0.3327}, and coefficients of a high pass filter (HPF) for performing high pass filtering may be {0.3327, 0.8069, −0.4599, −0.1350, 0.0854, 0.0352}.

The SOC of the battery may be estimated based on an extended Kalman filter (EKF).

According to one or more embodiments of the present invention, a battery management system (BMS) including: a collection unit for collecting terminal voltage data by periodically measuring a terminal voltage of the battery; an extraction unit for extracting voltage data of a low frequency component by performing DWT-based multi-resolution analysis on the terminal voltage data; and an SOC estimation unit for estimating the SOC of the battery based on the voltage data of the low frequency component.

### BRIEF DESCRIPTION OF THE DRAWINGS

These and/or other aspects will become apparent and more readily appreciated from the following description of the embodiments, taken in conjunction with the accompanying drawings of which:

FIG. 1 is a schematic block diagram of a car system including a battery, a battery management system (BMS), and peripheral apparatuses of the BMS, according to an embodiment of the present invention;

FIG. 2 is a schematic block diagram of a BMS, according to an embodiment of the present invention;

FIG. 3 is a schematic block diagram of an extraction unit;

FIG. 4 is a schematic block diagram of a state of charge (SOC) estimation unit;

FIGS. 5A through 5D are diagrams for explaining an operation of an extraction unit;

FIG. 6A is a graph of voltage data of an actual terminal voltage and fifth voltage data of a low frequency component and a sum of first through fifth voltage data of a high frequency component that are extracted by performing discrete wavelet transform (DWT) based multi resolution analysis on the voltage data;

FIGS. 6B and 6C are enlarged graphs of the voltage data and the fifth voltage data of a low frequency component of FIG. 6A;

FIGS. 7A and 7B are graphs verifying the accuracy of SOC estimation, according to an embodiment of the present invention; and

FIG. 8 is a flowchart of a method of estimating an SOC of a battery, according to an embodiment of the present invention.

### DETAILED DESCRIPTION

Reference will now be made in detail to embodiments, examples of which are illustrated in the accompanying drawings. The present invention may, however, be embodied in many different forms and should not be construed as being limited to the embodiments set forth herein; rather, these embodiments are provided so that this disclosure will be thorough and complete, and will fully convey the concept of the inventive concept to one of ordinary skill in the art. It should be understood, however, that there is no intent to limit exemplary embodiments of the inventive concept to the particular forms disclosed, but conversely, exemplary embodiments of the inventive concept are to cover all modifications, equivalents, and alternatives falling within the spirit and scope of the inventive concept.

In the drawings, like reference numerals denote like elements, and the sizes or thicknesses of elements may be exaggerated for clarity of explanation.

The terminology used herein is for the purpose of describing particular embodiments and is not intended to limit the inventive concept. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. It will be understood that, although the terms “first”, “second”, etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of exemplary embodiments. It will be understood that when an element or layer is referred to as being “on” another element or layer, the element or layer can be directly on another element or layer or intervening elements or layers.

Unless defined differently, all terms used in the description including technical and scientific terms have the same meaning as generally understood by one of ordinary skill in the art. Terms as defined in a commonly used dictionary should be construed as having the same meaning as in an associated technical context, and unless defined in the description, the terms are not ideally or excessively construed as having formal meaning.

As such, variations from the shapes of the illustrations as a result, for example, due to manufacturing techniques and/or tolerances, are to be expected. Thus, exemplary embodiments should not be construed as limited to the particular shapes of regions illustrated herein but may include deviations in shapes that result, for example, from manufacturing.

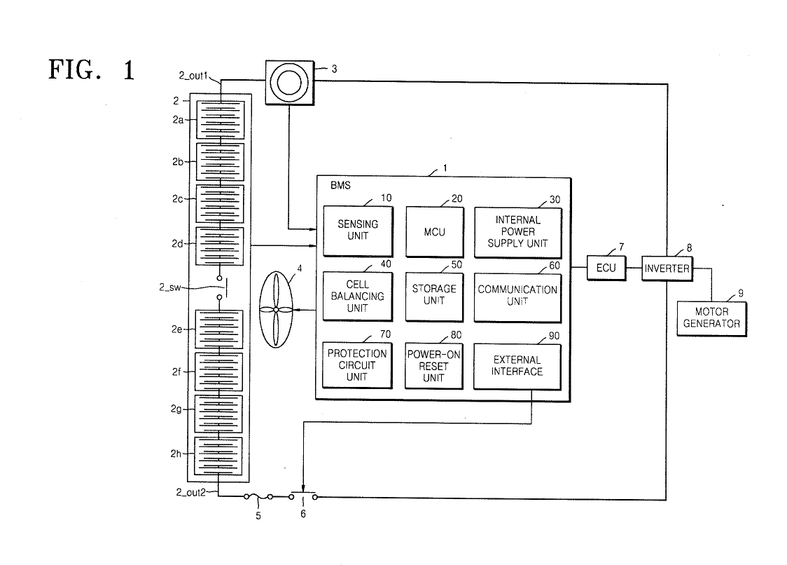

FIG. 1 is a schematic block diagram of a car system including a battery 2, a battery management system (BMS) 1, and peripheral apparatuses of the BMS, according to an embodiment of the present invention.

Referring to FIG. 1, the car system includes the BMS 1, the battery 2, a current sensor 3, a cooling fan 4, a fuse 4, a main switch 6, an engine controller unit (ECU) 7, an inverter 8, and a motor generator 9.

The battery 2 may include a plurality of sub packs 2a˜2h, a first input terminal 2_OUT1, a second output terminal 2_OUT2, and a security switch 2_SW disposed between the sub packs 2d and 2e. In this regard, the number of the sub packs 2a˜2h are exemplarily indicated as being 8. The sub packs 2a˜2h merely indicate a plurality of battery cells as a single group. The present invention is not limited to the number of the sub packs 2a˜2h. The security switch 2_SW is disposed between the sub packs 2d and 2e and may be manually turned on and off for security of an operator when batteries are exchanged or jobs are performed on batteries. Although the battery 2 includes the security switch 2_SW disposed between the sub packs 2d and 2e according to an embodiment of the present invention, the present invention is not limited thereto. The first input terminal 2_OUT1 and the second output terminal 2_OUT2 may be connected to an inverter 8.

The current sensor 3 may measure an output current amount of the battery 2 and output the measured output current amount to a sensing unit 10 of the BMS 1. In more detail, the current sensor 3 may be a Hall current transformer (CT) that measures a current by using a Hall element and outputs an analog current signal corresponding to the measured current.

The cooling fan 4 may cool heat generated by charging and discharging of the battery 2 based on a control signal of the. BMS 1 and prevent deterioration of the battery 2 and charging and discharging efficiency due to a temperature rise.

The fuse 5 may prevent an overcurrent from being transferred to the battery 2 due to a disconnection or a short circuit of the battery 2. That is, if the overcurrent is generated, the fuse 5 is disconnected to prevent the overcurrent from being transferred to the battery 2.

The main switch 6 may turn the battery 2 on and off based on the control signal of the BMS 1 or a control signal of the ECU 7 if an erroneous phenomenon such as an overvoltage, the overcurrent, a high temperature, etc. occurs.

The BMS 1 may include the sensing unit 10, a main control unit (MCU) 20, an internal power supply unit 30, a cell balancing unit 40, a storage unit 50, a communication unit 60, a protection circuit unit 70, a power-on reset unit 80, and an external interface 90. The BMS 1 may determine faults or deposit welding of relays disposed between the battery 2 and the inverter 8, for example, a main relay and an auxiliary relay.

The sensing unit 10 may measure and transmit a current of the battery 2 (hereinafter referred to as a “battery current”), a voltage of the battery 2 (hereinafter referred to as a “battery voltage”), pack voltages of the sub packs 2a˜2h (hereinafter referred to as a “pack voltage”), a cell voltage of each battery cell of the sub packs 2a˜2h (hereinafter referred to as a “cell voltage”), pack temperatures of the sub packs 2a˜2h, a peripheral temperature of the battery 2, etc. to the MCU 20. The sensing unit 10 may also measure and transmit a voltage of the inverter 8 to the MCU 20.

The MCU 20 may calculate a state of charge (SOC) or an internal resistance variation of the battery 2 based on the battery current, the battery voltage, the cell voltage of each battery cell, the pack temperature, and the peripheral temperature received from the sensing unit 10, calculate a state of health (SOH), and generate information regarding a state of the battery 2.

In more detail, in a case where the MCU 20 receives an analog signal corresponding to the battery voltage from the sensing unit 10, the MCU 20 may periodically sample the battery voltage, convert the sampled battery voltage into a digital value, and generate terminal voltage data. According to another example, the sensing unit 10 may generate terminal voltage data corresponding to the battery voltage and provide the generated terminal voltage data to the MCU 20.

The MCU 20 may perform discrete wavelet transform (DWT) based multi-resolution analysis on the terminal voltage data and extract voltage data of a low frequency component. The MCU 20 may generate SOC information by estimating the SOC of the battery 2 based on the voltage data of the low frequency component.

The internal power supply unit 30 may be generally an apparatus for supplying power to the BMS 1 using an auxiliary battery.

The cell balancing unit 40 may balance an SOC of each battery cell. That is, the cell balancing unit 40 may discharge a battery cell having an SOC that is higher than other battery cells and charge a battery cell having an SOC that is lower than other battery cells.

The storage unit 50 may store data such as a current SOC, SOH, etc. when power of the BMS 1 is off. In this regard, the storage unit 50 may be an electrically writable and erasable non-volatile storage apparatus such as electrically erasable programmable read-only memory (EEPROM) or flash memory.

The communication unit 60 may perform communication with the ECU 7. For example, the communication unit 60 may transmit information regarding the SOC and SOH from the BMS 1 to the ECU 7 or receive information regarding a car state from the ECU 7 and transmit the received information to the MCU 20.

The protection circuit unit 70 may be a circuit for protecting the battery 2 from an external shock, the overcurrent, a low voltage, etc. by using firmware.

The power-one reset unit 80 may reset the whole car system if the power of the BMS 1 is on.

The external interface 90 is an apparatus for connecting auxiliary apparatuses such as the cooling fan 4, the main switch 6, etc. to the MCU 20. Although only the cooling fan 4 and the main switch 6 are shown in the present embodiment, other elements may be further included.

The ECU 7 figures out a driving state of a car based on information such as an accelerator of the car, a break, a speed, etc. and determines information such as a size of a currently required torque. In more detail, the driving state of the car refers to a key on for turning on the ignition, a key off for turning off the ignition, constant driving, acceleration driving, etc. The ECU 7 may transmit the information regarding the state of the car to the communication unit 60. The ECU 7 may control an output of the motor generator 9 to fit the size of the required torque. That is, the ECU 7 may control switching of the inverter 8 so as to control the output of the motor generator 9 to fit the size of the required torque.

The ECU 7 may also receive the SOC of the battery 2 from the MCU 20 through the communication unit 60 of the BMS 1 and control the SOC of the battery 2 to have a target value (for example, 55%). For example, if the SOC of the battery 2 received from the MCU 20 is equal to or lower than 55%, the ECU 7 may control switching of the inverter 8 to output power in a direction of the battery 2 and charge the battery 2. In this regard, the battery current may be set as a “− value”. Meanwhile, if the SOC of the battery 2 received from the MCU 20 is equal to or higher than 55%, the ECU 7 may control switching of the inverter 8 to output power in a direction of the motor generator 9 and discharge the battery 2. In this regard, the battery current may be set as a “+ value”.

The inverter 8 may charge or discharge the battery 2 based on the control signal of the ECU 7.

The motor generator 9 may drive the car based on information regarding the size of the required torque received from the ECU 7 by using electric energy of the battery 2.

The ECU 7 may be charged and discharged based on the SOC so that the battery 2 may be prevented from being overcharged or overdischarged and may be efficiently used for a long time. However, after the battery 2 is installed in the car, since it is difficult to directly measure an actual SOC of the battery 2, the BMS 1 needs to accurately measure the SOC using the battery voltage, the battery current, the cell temperature, etc. sensed by the sensing unit 10 and transmit the measured SOC to the ECU 7.

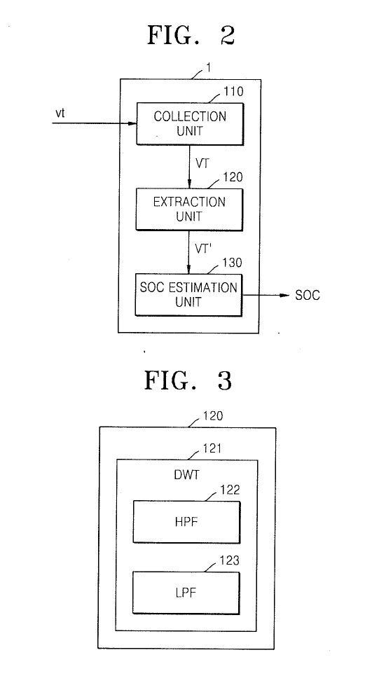

FIG. 2 is a schematic block diagram of the BMS 1, according to an embodiment of the present invention.

Referring to FIG. 2, the BMS 1 may include a collection unit 110, an extraction unit 120, and an SOC estimation unit 130.

The collection unit 110 may periodically measure a terminal voltage vt of a battery and collect terminal voltage data VT. In this regard, the battery may refer to the battery 2 of FIG. 1. The battery may refer to each of the sub packs 2a˜2h or each battery cell of the sub packs 2a˜2h according to a unit of a battery whose SOC is to be calculated.

The terminal voltage vt may refer to a difference between a voltage of the first output terminal 2_out1 and a voltage of the second output terminal 2_out2 of FIG. 1. However, in a case where the SOC is calculated in units of the sub packs 2a˜2h, the terminal voltage vt may refer to an output voltage of each of the sub packs 2a˜2h, i.e. a pack voltage. In a case where the SOC is calculated in units of battery cells, the terminal voltage vt may refer to a cell voltage.

The collection unit 110 may periodically sample the terminal voltage vt of the battery and generate the terminal voltage data VT. For example, the collection unit 110 may measure the terminal voltage vt of the battery at a time interval such as 1 sec, 0.1 sec, 0.01 sec, etc., digitize the measured terminal voltage vt, and generate the terminal voltage data VT. To this end, the collection unit 110 may include an analog-digital converter (ADC) (not shown).

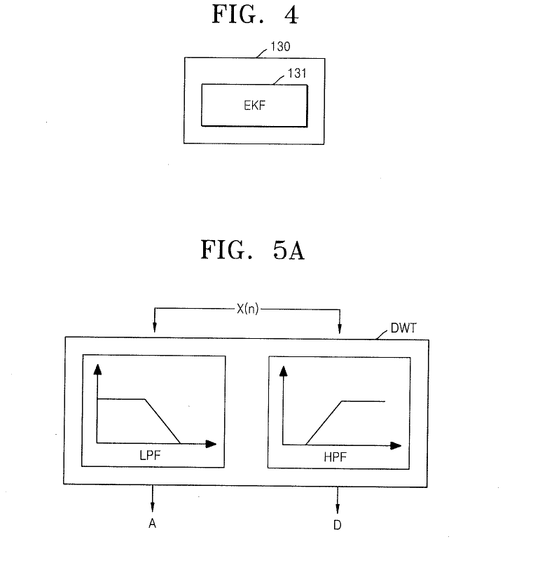

The extraction unit 120 may perform DWT-based multi resolution analysis on the terminal voltage data VT and extract voltage data VT′ of a low frequency. FIG. 3 is a schematic block diagram of the extraction unit 120. Referring to FIG. 3, the extraction unit 120 may perform DWT 121 on the terminal voltage data VT.

The DWT 121 may separate the terminal voltage data VT into voltage data of a low frequency component and the voltage data VT′ of a high frequency component. The extraction unit 120 may include a high pass filter (HPF) 122 for extracting voltage data of a high frequency component from the terminal voltage data VT and a low pass filter (LPF) 123 for extracting the voltage data VT′ of the low frequency component from the terminal voltage data VT. The HPF 122 and the LPF 123 are not implemented in a physical and circuit manner but may be implemented by data processing.

The terminal voltage data VT may be separated into voltage data of a plurality of frequency bands through the DWT-based multi resolution analysis. For example, the terminal voltage data VT may be separated into voltage data of a first frequency band (for example, a frequency band greater than f₀), a second frequency band (for example, a frequency band smaller than f₀ and greater than f₀/2), a third frequency band (for example, a frequency band smaller than f₀/2 and greater than f₀/4), a fourth frequency band (for example, a frequency band smaller than f₀/4 and greater than f₀/8), a fifth frequency band (for example, a frequency band smaller than f₀/8 and greater than f₀/16), and a sixth frequency band (for example, a frequency band smaller than f₀/16). In this regard, the voltage data VT′ of the low frequency extracted by the extraction unit 120 may be the voltage data of the sixth frequency band (for example, the frequency band smaller than f₀/16).

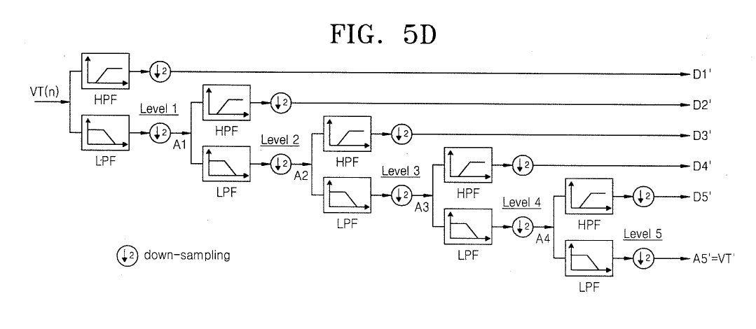

The extraction unit 120 will be described in more detail with reference to FIGS. 5A through 5D below.

The SOC estimation unit 130 may estimate an SOC of the battery based on the voltage data VT′ of the low frequency component and provide the estimated SOC to the ECU 7 through, for example, the communication unit 60 of FIG. 1.

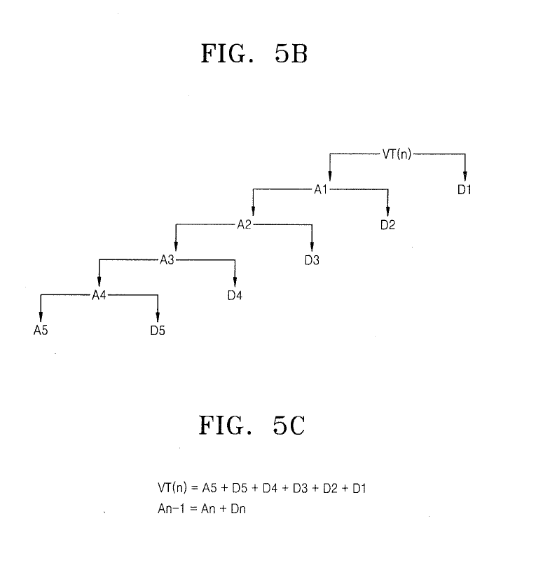

The SOC estimation unit 130 may estimate the SOC of the battery based on an extended Kalman filter (EKF). FIG. 4 is a schematic block diagram of the SOC estimation unit 130. As shown in FIG. 4, the SOC estimation unit 130 may include an EKF 131.

A battery terminal voltage and an input current are necessary for estimating the SOC based on the EKF 131. An open circuit voltage (OCV) calculation equation and an OCV and SOC relationship need to be determined by using a parameter value of an equivalent circuit model of the battery. According to the present invention, the voltage data VT′ of the low frequency component extracted by the extraction unit 120 is provided to the SOC estimation unit 130 instead of the voltage data of the terminal voltage of the battery.

As described above, data such as current data may be input into the SOC estimation unit 130 in addition to the voltage data VT′ of the low frequency component. Also, as described above, the OCV calculation equation and the OCV and SOC relationship according to the equivalent circuit model of the battery may be built in the SOC estimation unit 130. The equivalent circuit model applied to the SOC estimation unit 130 may not include a noise model.

FIGS. 5A through 5D are diagrams for explaining an operation of the extraction unit 120.

FIG. 5A shows that if DWT is performed on input data x(n), proximity data A and detailed data D are generated. In more detail, if low pass filtering is performed on the input data x(n) by using an LPF, the proximity data A is extracted. Also, if high pass filtering is performed on the input data x(n) by using an HPF, the detailed data D is extracted. The LPF and the HPF need to be implemented to perform the DWT.

For example, coefficients of the LPF may be {0.0352, −0.0854, −0.1350, 0.4599, 0.8069, 0.3327}, and coefficients of the HPF may be {0.3327, 0.8069, −0.4599, −0.1350, 0.0854, 0.0352}.

FIG. 5B shows DWT-based multi resolution analysis. Although the DWT is repeatedly performed five times in FIG. 5B, the repeating number of the DWT is not limited thereto. The DWT may be performed only once or may be repeatedly performed more than five times.

Voltage data VT(n) may be separated into first proximity voltage data A1 and first detailed voltage data D1 through first DWT. The first proximity voltage data A1 may be separated into second proximity voltage data A2 and second detailed voltage data D2 through second DWT. The second proximity voltage data A2 may be separated into third proximity voltage data A3 and third detailed voltage data D3 through third DWT. The third proximity voltage data A3 may be separated into fourth proximity voltage data A4 and fourth detailed voltage data D4 through fourth DWT. The fourth proximity voltage data A4 may be separated into fifth proximity voltage data A5 and fifth detailed voltage data D5 through fifth DWT. In this regard, the fifth proximity voltage data A5 may be output as the voltage data VT′ of the low frequency component by the extraction unit 120.

Therefore, as shown in FIG. 5C, the voltage data VT(n) may include a sum of the fifth proximity voltage data A5 and the first through fifth detailed voltage data D1 through D5. Also, n-1th proximity voltage data A(n-1) may be expressed as a sum of nth proximity voltage data An and nth detailed voltage data Dn. Thus, if there are the fifth proximity voltage data A5 and the first through fifth detailed voltage data D1 through D5, the voltage data VT(n) may be restored. Such a restoration process may be referred to as inverse DWT (IDWT).

As shown in FIG. 5B, if the DWT is repeatedly performed, an overall data amount increases since voltage data is separated into proximity voltage data and detailed voltage data. Thus, after the DWT is performed, down-sampling may be performed. Down-sampling means that even numbered data or odd numbered data of proximity voltage data generated by previous DWT is selected, and non-selected data is removed. The selected data may be referred to as proximity voltage sampling data.

As shown in FIG. 5D, the voltage data Vt may be separated into the first detailed voltage data D1 and the first proximity voltage data Al through high pass filtering and low pass filtering. Down-sampling is performed on the first detailed voltage data D1 and the first proximity voltage data A1 so that first detailed voltage sampling data D1′ and first proximity voltage sampling data A1′ may be generated. The first proximity voltage sampling data A1′ may be separated into the second detailed voltage data D2 and the second proximity voltage data A2 through high pass filtering and low pass filtering. Down-sampling is performed on the detailed voltage data D2 and the second proximity voltage data A2 so that second detailed voltage sampling data D2′ and second proximity voltage sampling data A2′ may be generated. The second proximity voltage sampling data A2′ may be separated into the third detailed voltage data D3 and the third proximity voltage data A3 through high pass filtering and low pass filtering. Down-sampling is performed on the third detailed voltage data D3 and the third proximity voltage data A3 so that third detailed voltage sampling data D3′ and third proximity voltage sampling data A3′ may be generated. The third proximity voltage sampling data A3′ may be separated into the fourth detailed voltage data D4 and the fourth proximity voltage data A4 through high pass filtering and low pass filtering. Down-sampling is performed on the fourth detailed voltage data D4 and the fourth proximity voltage data A4 so that fourth detailed voltage sampling data D4′ and fourth proximity voltage sampling data A4′ may be generated. The fourth proximity voltage sampling data A4′ may be separated into the fifth detailed voltage data D5 and the fifth proximity voltage data A5 through high pass filtering and low pass filtering. Down-sampling is performed on the fifth detailed voltage data D5 and the fifth proximity voltage data A5 so that fifth detailed voltage sampling data D5′ and fifth proximity voltage sampling data A5′ may be generated. In this regard, the fifth proximity voltage sampling data A5′ may be the voltage data VT′ of the low frequency component output by the extraction unit 120.

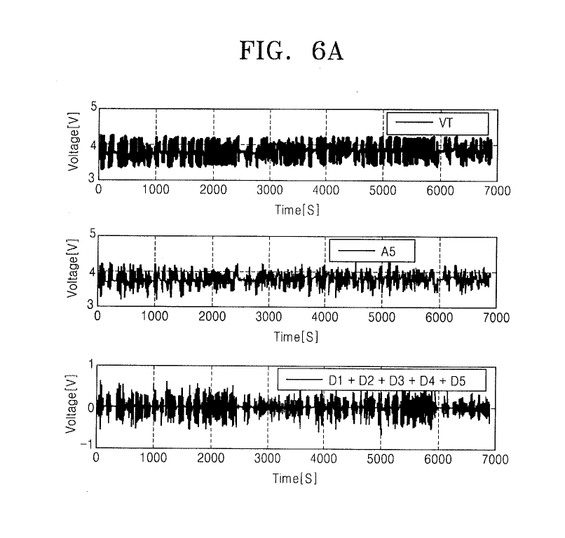

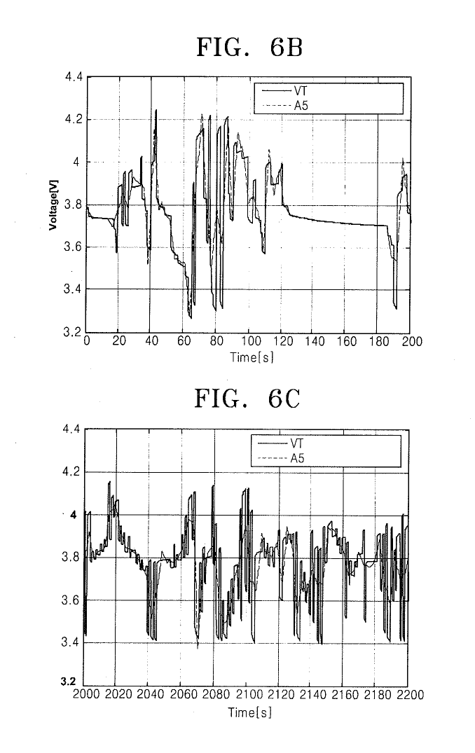

FIG. 6A is a graph of the voltage data VT of an actual terminal voltage and the fifth voltage data A5 of a low frequency component and a sum of the first through fifth voltage data D1 through D5 of a high frequency component that are extracted by performing DWT-based multi resolution analysis on the voltage data VT.

FIGS. 6B and 6C are enlarged graphs of the voltage data VT and the fifth voltage data A5 of a low frequency component of FIG. 6A. The graph of FIG. 6B is enlarged between 0 sec and 200 sec. The graph of FIG. 6C is enlarged between 2000 sec and 220 sec.

As shown in FIG. 6A, the fifth voltage data A5 of a low frequency component is similar to the voltage data VT, whereas the sum of the first through fifth voltage data D1 through D5 of a high frequency component is slightly different from the voltage data VT.

Referring to FIGS. 6B and 6C, similarity between the fifth voltage data A5 of a low frequency component and the voltage data VT is more clearly shown. A difference between the fifth voltage data A5 of a low frequency component and the voltage data VT may correspond to the sum of the first through fifth voltage data D1 through D5 of a high frequency component.

In a part where the voltage data VT does not greatly change, the fifth voltage data A5 of a low frequency component and the voltage data VT are almost the same. That is, if an influence of a high frequency component is not great, the actual terminal voltage and voltage data (the fifth voltage data A5 of a low frequency component in FIG. 5D) of a final low frequency component are generally similar to each other. Among noise models applied to the conventional EKF, a measurement noise model regarding a rapid current variation and a fast dynamic concerns a rapid current variation or a frequency condition. Thus, the The voltage data A5 of the final low frequency component is that a high frequency voltage component relating to the rapid current variation or a fast dynamics is excluded from the actual terminal voltage.

As shown in FIGS. 6B and 6C, with respect to a long charging or discharging time, there is little difference between the actual terminal voltage and the voltage data A5 of the final low frequency component. However, in a case where charging and discharging frequently alternate within a short period of time, the difference between the actual terminal voltage and the voltage data A5 of the final low frequency component increases. Such a difference may be caused by the rapid current variation and the fast dynamics.

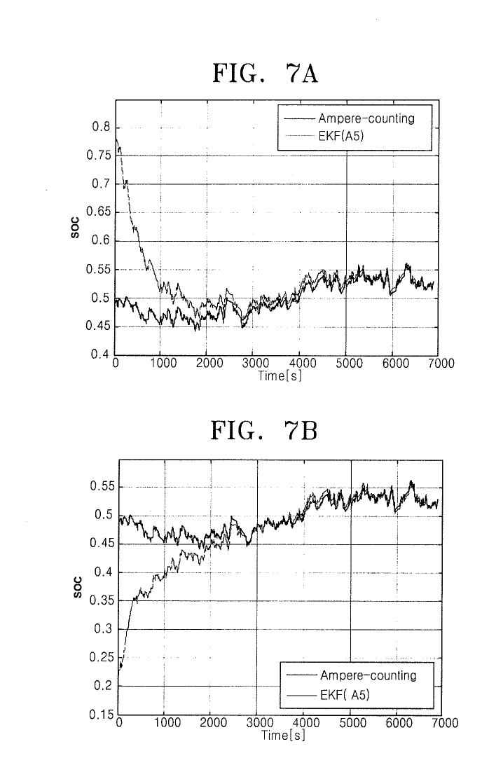

FIGS. 7A and 7B are graphs verifying accuracy of SOC estimation, according to an embodiment of the present invention.

The graphs of FIGS. 7A and 7B include an SOC (indicated as “Ampere-counting”) calculated by current integration and an SOC estimated by using an EKF based on the voltage data of a final low frequency component according to the present invention. In FIG. 7A, an initial SOC is set as 0.8. In FIG. 7B, the initial SOC is set as 0.2.

As shown in FIGS. 7A and 7B, even if the initial SOC is set differently, the SOC estimated based on the EKF and the SOC calculated by the current integration have the same results. Even if a noise model is not applied, it may be seen that the SOC estimation performance does not deteriorate by using the voltage data A5 of the final low frequency component.

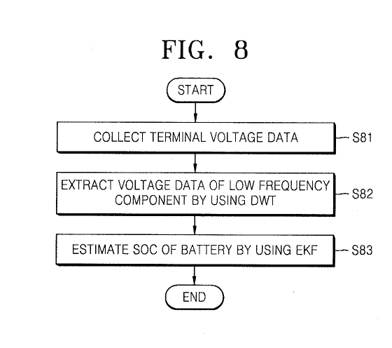

FIG. 8 is a flowchart of a method of estimating an SOC of a battery, according to an embodiment of the present invention.

Referring to FIG. 8, in operation 81, terminal voltage data is collected. A terminal voltage of a battery is periodically measured, a measured voltage value is digitized, and the terminal voltage data may be sensed. The terminal voltage data may be collected by the sensing unit 10 of FIG. 1 or by the sensing unit 10 and the MCU 20. An ADC may be necessary for generating the terminal voltage data that is digital data.

In operation 82, DWT-based multi resolution analysis is performed on the terminal voltage data, and voltage data of a low frequency component is extracted from the terminal voltage data. The voltage data of a low frequency component may be extracted by the MCU 20 of FIG. 1. The MCU 20 may perform DWT and include a high pass filter and a low pass filter.

In operation 83, an SOC of the battery is estimated by using an EKF based on the extracted voltage data of a low frequency component. The SOC of the battery may be estimated by the MCU 20 of FIG. 1. The MCU 20 may include the EKF.

An inner state of a system needs to be ideally infinite so as to increase the estimation performance of an SOC estimation algorithm based on the EKF. However, this is actually impossible. A method of reducing the internal state of the system to the minimum and maintaining the performance of the SOC estimation algorithm has been proposed. According to the method, areas causing deterioration of the SOC estimation performance, for example, an area having a very high or low SOC, an area having a very high current, and an area including a fast dynamics, are determined as non-reliability regions, and a noise model is used to maintain the SOC estimation performance. However, an addition of the noise model causes increases in algorithm complexity and accordingly expenses.

The present invention applies an algorithm that is concise and improved compared to the conventional art while maintaining excellent SOC estimation performance, thereby solving time and expense problems due to system development.

In more detail, an actual terminal voltage may be separated into a low frequency voltage component and a high frequency voltage component through DWT. As described above, voltage characteristics of the non-reliability regions generally have a characteristic of the high frequency voltage component. The low frequency voltage component calculated through DWT-based multi resolution analysis and the actual terminal voltage generally have similar characteristics. The low frequency voltage component according to the present invention does not include the high frequency voltage component and thus the conventional noise model may be omitted. In a case where the SOC estimation algorithm based on the EKF is driven by using the low frequency voltage component as a battery terminal voltage in the SOC estimation algorithm, it was confirmed that similar performance to the conventional method of adding the noise mode is exhibited.

That is, in a case where the low frequency voltage component is used as the terminal voltage of the SOC estimation algorithm according to the present invention, the algorithm may be concise while maintaining the SOC estimation algorithm of a BMS, and accordingly expenses may be reduced.

The concept of the present invention may be applied to battery SOC estimation of an energy storage system as well as of a car system. In more detail, according to the present invention, a low frequency component may be extracted from a terminal voltage of a battery pack or a battery module of the energy storage system through DWT, and an SOC may be estimated based on the low frequency component.

It should be understood that the exemplary embodiments described herein should be considered in a descriptive sense only and not for purposes of limitation. Descriptions of features or aspects within each embodiment should typically be considered as available for other similar features or aspects in other embodiments.

What is claimed is:

1. A method of estimating a state of charge (SOC) of a battery, the method comprising:
collecting terminal voltage data by periodically measuring a terminal voltage of the battery;
extracting voltage data of a low frequency component by performing discrete wavelet transform (DWT) based multi-resolution analysis on the terminal voltage data; and
estimating the SOC of the battery based on the voltage data of the low frequency component.

2. The method of claim 1, wherein the terminal voltage data is separated into voltage data of a plurality of frequency bands through the DWT-based multi-resolution analysis.

3. The method of claim 2, wherein the voltage data of the low frequency component is voltage data of a lowest frequency band from among the voltage data of the plurality of frequency bands.

4. The method of claim 1, wherein the extracting of the voltage data of the low frequency component comprises: separating the terminal voltage data into first proximity voltage data and first detailed voltage data by performing low pass filtering and high pass filtering on the terminal voltage data.

5. The method of claim 4, wherein the extracting of the voltage data of the low frequency component comprises: generating first proximity voltage sampling data by performing down-sampling on the first proximity voltage data to select odd numbered data or even numbered data of the first proximity voltage data.

6. The method of claim 5, wherein the extracting of the voltage data of the low frequency component comprises: separating the first proximity voltage sampling data into second proximity voltage data and second detailed voltage data by performing low pass filtering and high pass filtering on the first proximity voltage sampling data.

7. The method of claim 6, wherein the extracting of the voltage data of the low frequency component comprises: separating the terminal voltage data into nth proximity voltage data and first through nth detailed voltage data (where n is a natural number) by repeating operations of performing down-sampling and performing high pass filtering and low pass filtering.

8. The method of claim 7, wherein the voltage data of the low frequency component is the nth proximity voltage data.

9. The method of claim 4, wherein coefficients of a low pass filter (LPF) for performing low pass filtering are {0.0352, −0.0854, −0.1350, 0.4599, 0.8069, 0.3327}, and coefficients of a high pass filter (HPF) for performing high pass filtering are {0.3327, 0.8069, −0.4599, −0.1350, 0.0854, 0.0352}.

10. The method of claim 1, wherein the estimating of the SOC of the battery comprises: estimating the SOC of the battery based on an extended Kalman filter (EKF).

11. A battery management system (BMS) comprising:
a collection unit for collecting terminal voltage data by periodically measuring a terminal voltage of the battery;
an extraction unit for extracting voltage data of a low frequency component by performing DWT-based multi-resolution analysis on the terminal voltage data; and
an SOC estimation unit for estimating the SOC of the battery based on the voltage data of the low frequency component.

12. The BMS of claim 11, wherein the terminal voltage data is separated into voltage data of a plurality of bands through the multi-resolution DWT-based analysis.

13. The BMS of claim 12, wherein the voltage data of the low frequency component is voltage data of a lowest frequency band from among the voltage data of the plurality of bands.

14. The BMS of claim 11, wherein the extraction unit separates the terminal voltage data into first proximity voltage data and first detailed voltage data by performing low pass filtering and high pass filtering on the terminal voltage data.

15. The BMS of claim 14, wherein the extraction unit generates first proximity voltage sampling data by performing down-sampling on the first proximity voltage data to select odd numbered data or even numbered data of the first proximity voltage data.

16. The BMS of claim 15, wherein the extraction unit separates the first proximity voltage sampling data into second proximity voltage data and second detailed voltage data by performing low pass filtering and high pass filtering on the first proximity voltage sampling data.

17. The BMS of claim 16, wherein the extraction unit separates the terminal voltage data into nth proximity voltage data and first through nth detailed voltage data (where n is a natural number) by repeating operations of performing down-sampling and performing high pass filtering and low pass filtering.

18. The BMS of claim 17, wherein the voltage data of the low frequency component is the nth proximity voltage data.

19. The BMS of claim 14, wherein the extraction unit comprises a low pass filter (LPF) for performing low pass filtering and a high pass filter (HPF) for performing high pass filtering,
wherein coefficients of the LPF are {0.0352, −0.0854, −0.1350, 0.4599, 0.8069, 0.3327}, and coefficients of the HPF of are {0.3327, 0.8069, −0.4599, −0.1350, 0.0854, 0.0352}.

20. The BMS of claim 14, wherein the SOC estimation unit estimates the SOC of the battery based on an EKF.
